(19) United States
(12) Patent Application Publication
(10) Pub. No.: US 2007/0081409 A1
(43) Pub. Date: Apr. 12, 2007

(54) Reduced bitline leakage current

(76) Inventors: John J. Wuu, Fort Collins, CO (US); Jonathan E. Lachman, Fort Collins, CO (US); Donald R. Weiss, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/234,480

(22) Filed: Sep. 23, 2005

(51) Int. Cl. G11C 5/14

(52) U.S. Cl. 365/227

(57) ABSTRACT

A method for reducing power in an SRAM is achieved by applying a first voltage to all bitlines of a section of the SRAM in standby operation and applying a second voltage to all the bitlines of a section of the SRAM in normal operation. The first voltage is not greater than the second voltage.

### FIELD OF THE INVENTION

This invention relates generally to electronic circuits. More particularly, this invention relates to reducing power in SRAMs.

### BACKGROUND OF THE INVENTION

As more electronic circuits are included on a single die, the power dissipated by a single die continues to increase. In order to keep the temperature of a single IC (integrated circuit) reasonable to maintain reliability, many techniques have been used. For example, elaborate cooling fins have been attached to the substrate of ICs. Also, fans have been positioned near a group of IC's to cool them. In some cases, liquids have been used to more rapidly remove the heat produced by ICs. These solutions can be costly and may require a great deal of space, where space is at a premium. If the power on ICs can be reduced while still achieving higher levels of integration, the cost and volume of devices that use ICs may be reduced.

The number of bits contained on semiconductor chips containing memory, has, on average, quadrupled every three years. As a result, the power that semiconductor memories consume has increased. Computer systems may use large numbers of on-chip and stand-alone semiconductor memories. Part of the semiconductor memory used by these computer systems may be held in standby mode for a certain amount of time. The portion of memory that is held in standby is not accessed for data and as result, has lower power requirements than those parts of semiconductor memory that are accessed. Part of the power used in stand-by mode is created by leakage current in each individual memory cell of the semiconductor memory. Because the amount of memory used in a computer system or as part of a microprocessor chip is increasing, the power, as result of leakage current in semiconductor memory cells, is also increasing. The following description of a system and method for reducing the leakage current on bitlines of SRAMs addresses a need in the art to reduce power in ICs and computer systems.

### BRIEF DESCRIPTION OF THE DRAWINGS

FIG. 1 is a cross-sectional drawing of a NFET transistor. Prior Art

FIG. 2 is a schematic drawing of a SRAM memory cell. Prior Art

FIG. 3 is a schematic drawing of a memory array. Prior Art

FIG. 4 is a schematic drawing of a single bitline pair with a pair of PFETs used to precharge the bitlines. Prior Art

FIG. 5 depicts a schematic of an exemplary system for reducing power on an SRAM.

FIG. 5A is an example of normal and standby operation of an SRAM.

FIG. 6 depicts a schematic of an exemplary system for reducing power on an SRAM.

FIG. 7 depicts a schematic of an exemplary system for reducing power on an SRAM.

FIG. 8 depicts a schematic of an exemplary system for reducing power on an SRAM.

FIG. 9 depicts a schematic of an exemplary system for reducing power on an SRAM.

FIG. 10 depicts a block diagram of an exemplary computer system for reducing power on an SRAM.

### DETAILED DESCRIPTION OF THE PREFERRED EMBODIMENT

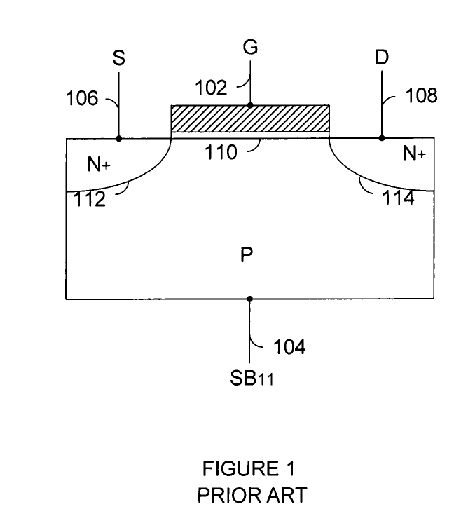

In FIG. 1, a cross-section of a NFET is illustrated. Node 102 is connected to a conducting material, poly-silicon or metal which forms, along with 110, a thin oxide, a gate, G of the NFET. Node 106 is connected to a N+ diffusion that forms the source, S, of the NFET. Node 108 is connected to a N+ diffusion that forms the drain, D, of the NFET. Node 104 is connected to a P-type material that forms the substrate, SB, of the NFET. The four nodes, 102, 104, 106, and 108 may be used to control the NFET. The voltage on node 104 must be at about the same voltage or lower than the voltages on nodes 106 and 108 in order to maintain a reverse bias. If the voltage on nodes 106 or 108 goes lower than the substrate, 104, by approximately 0.7 volts, the diode formed by the P/N junction of node 112 or node 114 will forward bias and conduct current. This is usually not desired when using a NFET as a switch.

When node 102, G, is charged to a “high” voltage, a conductive N-type channel forms under the oxide, 110, electrically connecting nodes 106 and 108. When node 102, G, is charged to a “low” voltage, a significant channel does not form under the oxide, 110, and very little current can flow between nodes 106 and 108. The condition where a “low” voltage is applied to 102 is usually called “off” because only a small amount of current flows between nodes 106 and 108. However, even when the NFET is off, with a low voltage applied to node 102, the current flowing between nodes 106 and 108 is not zero. If a design, for a example an SRAM, uses billions of NFETs and has the majority of the NFETs turned “off”, there can still be a relatively large loss of power due to the “small” leakage current contributed by the billions of individual NFETs. This drain-to-source leakage current may be reduced by lowering the voltage on either nodes 102 or 108, or on both nodes 102 and 108.

Leakage current also occurs across reversed biased p/n junctions. In FIG. 1, a reversed p/n junction is created between nodes 106 and 104 when the voltage on node 106 is greater than the voltage on node 104. In FIG. 1, a reversed p/n junction is created between nodes 108 and 104 when the voltage on node 108 is greater than the voltage on node 104. Leakage current, however, may increase as the voltage on nodes 108 and 106 increases with respect to node 104. Leakage current may be reduced by lowering the voltage on nodes 106 and 108 relative to node 104.

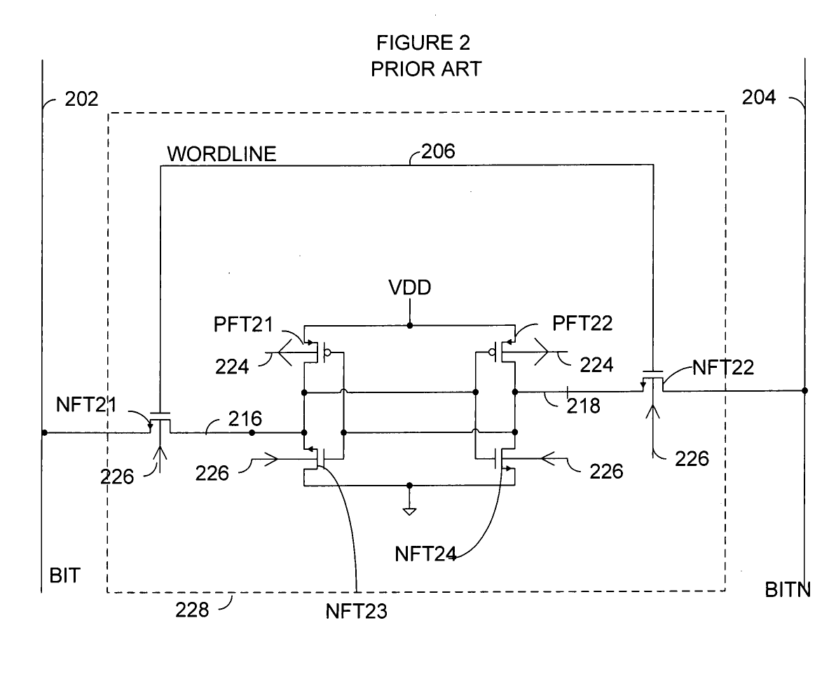

FIG. 2 is a schematic drawing of a six transistor SRAM memory cell, 228. The source of PFET, PFT21, and the source of PFET, PFT22 are connected to VDD. The drain, 216, of PFET, PFT21, the drain, 216 of NFET, NFT23, and the drain, 216 of NFET, NFT21 are connected at node 216. The drain, 218 of PFET, PFT22, the drain, 218 of NFET, NFT24, and the drain, 218 of NFET, NFT22 are connected at node 218. The source of NFET, NFT23 and the source of NFET, NFT24 are connected to GND. The gates of PFET, PFT21 and NFET, NFT23 are connected to node 218. The gates of PFET, PFT22 and NFET, NFT24 are connected to node 216. The gates of NFETs, NFT21 and NFT22, are connected to node 206, WORDLINE. The source of NFET, NFT21 is connected node 202, BIT and the source of NFET, NFT22 is connected node 204, BITN. The substrates of NFETS, NFT21, NFT22, NFT23, and NFT24 are connected to node 226. Node 226 may be grounded or a negative voltage may be applied. The Nwells of PFETs, PFT21 and PFT22, are connected at node 224. Leakage current may be reduced by lowering the voltage on nodes 202, 204 and VDD.

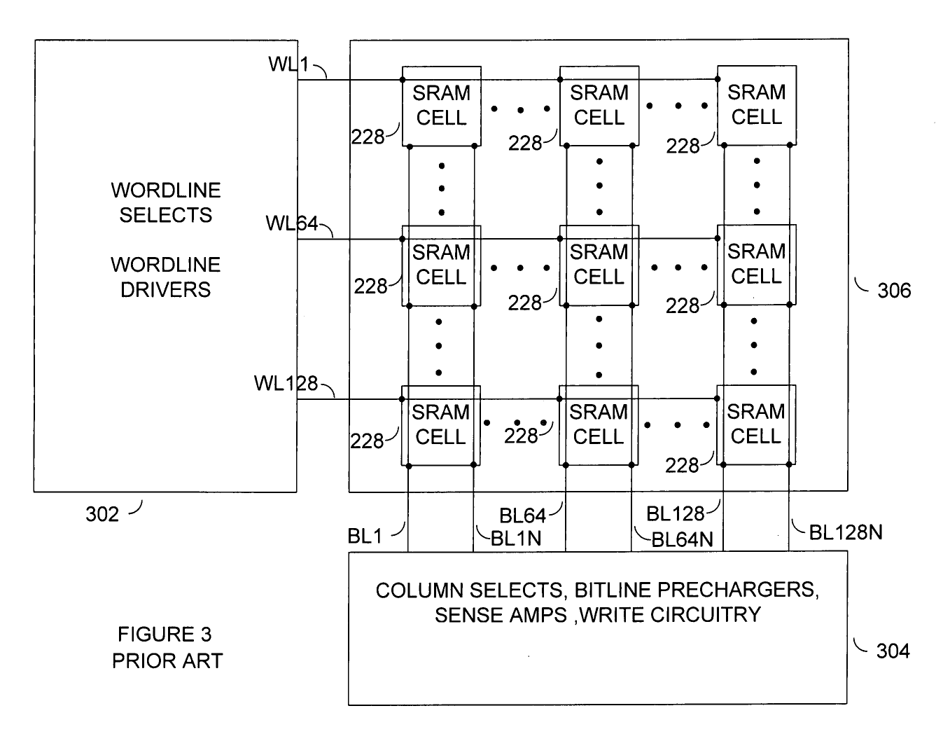

FIG. 3 is a schematic drawing of an SRAM. Circuitry, 302, includes wordline selects, and wordline drivers. The wordline drivers drive the wordlines WL1-WL128 in this example. The voltage on the wordlines, WL1-WL128, should be high enough to write and read the SRAM cells, 228.

Other circuitry, 304, includes column selects, bitline prechargers, sense amps, and write circuitry. Bitline prechargers charge bitline pairs, BL1-BL1N through BL128-BL128N. The bitline pairs, BL1-BL1N through BL128-BL128N, should be charged to a high enough voltage that allows the SRAM cells, 228, to be stable when read during normal operation. During standby operation the voltage on bitline pairs, BL1-BL1N through BL128-BL128N, may be lowered to reduce leakage current and save power.

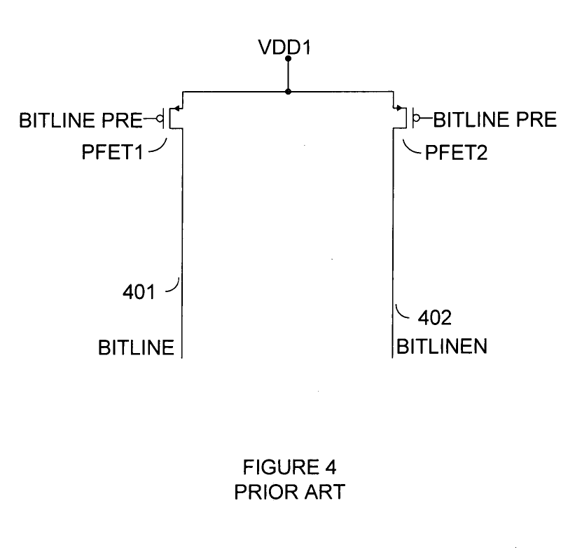

FIG. 4 is a schematic drawing of a single bitline pair with a pair of PFETs used to precharge the bitlines. After reading or writing BITLINE, 401, and BITLINEN, 402, PFET1 charges BITLINE, 401, to near VDD1 and PFET2 charges BITLINE, 402, to near VDD1. In this case the bitlines, 401 and 402, are precharged to near VDD1 during normal operation and during standby operation. The bitlines are precharged to a voltage near VDD1 by driving the signal, BITLINE PRE, to a low logical value.

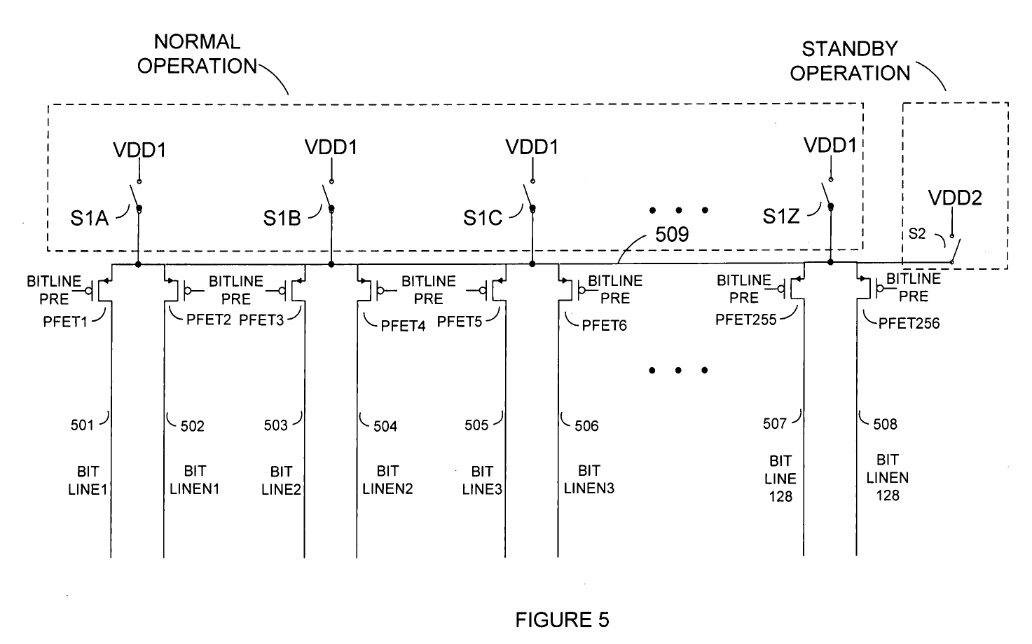

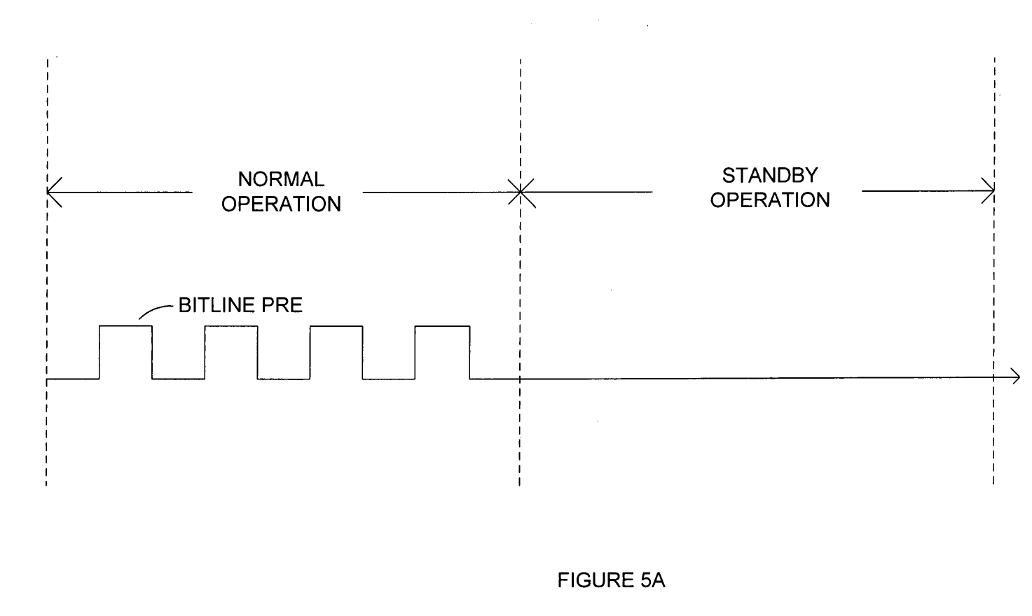

FIG. 5A is an example of normal and standby operation of an SRAM. The BITLINE PRE signal is shown as a function of time. The SRAM is in normal operation when the BITLINE PRE signal is toggling for a period of time. The SRAM is in standby operation when the BITLINE PRE signal is not toggling for a period of time.

FIG. 5 depicts a schematic of an exemplary system for reducing power in an SRAM. During normal operation switches, S1A-S1Z, close and connect node 509 to VDD1. Also during normal operation switch, S2, is open. During standby operation switch, S2, closes and connects node 509 to VDD2. Also during standby operation switches, S1A-S1Z, are open. In this example, VDD2 is a voltage lower than VDD1. Because VDD2 is a lower voltage than VDD1, the power used due to leakage is reduced. A switch in this example represents any means for connecting a power supply to node 509.

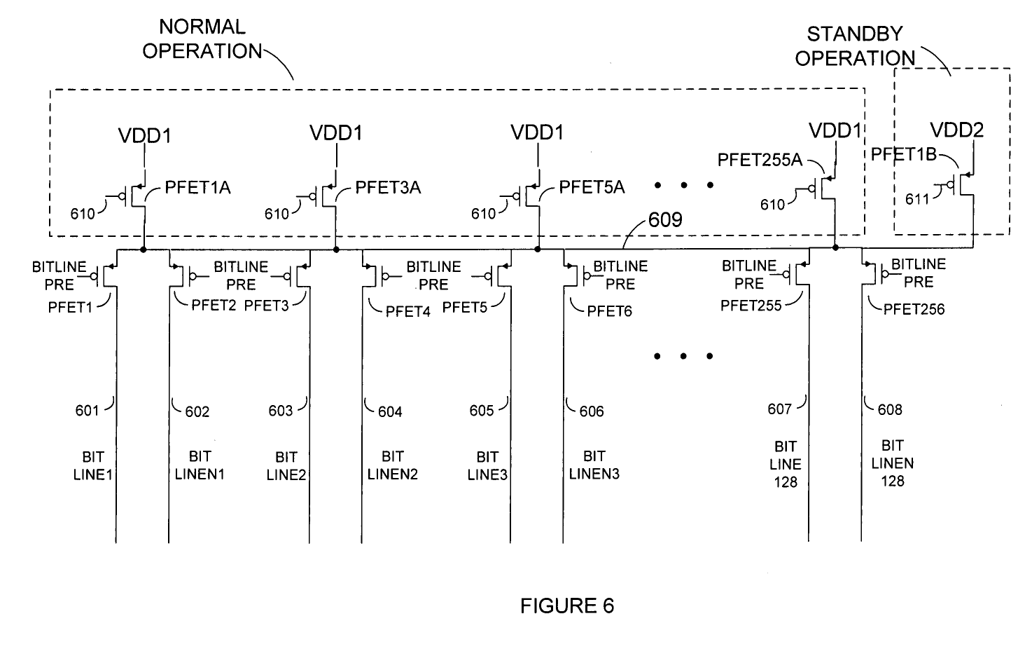

FIG. 6 depicts a schematic of an exemplary system for reducing power in an SRAM. During normal operation node 610 is driven to a low logical value and node 611 is driven to a high logical value. Because node 610 is driven to a low logical value and node 611 is driven to a high logical value, PFETs, PFET1A-PFET255A drive node 609 to a voltage near VDD1. During standby operation node 610 is driven to a high logical value and node 611 is driven to a low logical value. Because node 610 is driven to a high logical value and node 611 is driven to a low logical value, PFET1B drives node 609 to a voltage near VDD2. In this example, VDD2 is a voltage lower than VDD1. Because VDD2 is a lower voltage than VDD1, the power used due to leakage is reduced.

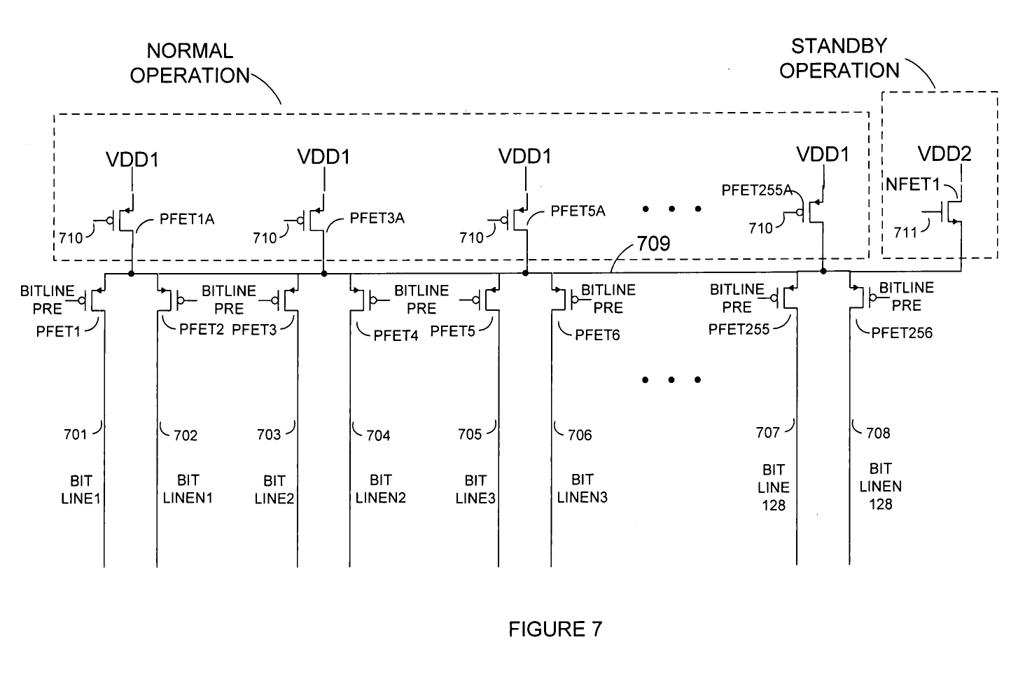

FIG. 7 depicts a schematic of an exemplary system for reducing power in an SRAM. During normal operation node 710 is driven to a low logical value and node 711 is driven to a low logical value. Because node 710 is driven to a low logical value and node 711 to a low logical value, PFETs, PFET1A-PFET255A drive node 709 to a voltage near VDD1. During standby operation node 710 is driven to a high logical value and node 711 is driven to a high logical value. Because node 710 is driven to a high logical value and node 711 to a high logical value, NFET1 drives node 709 to a voltage near VDD2−Vₜ. In this example, NFET, NFET1, drops the voltage on node 709 to a voltage one Vₜ lower than VDD2. Because NFET1 drops the voltage on node 709 to a voltage one Vₜ lower than VDD2, the power used due to leakage is reduced. In this case the voltage, VDD2−Vₜ, is lower than VDD1.

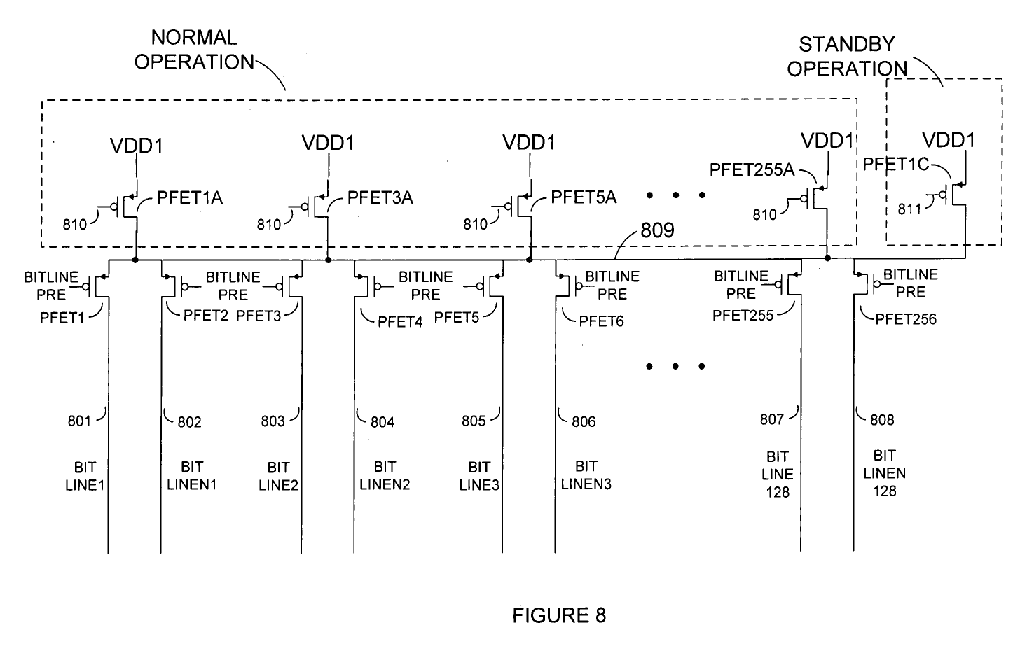

FIG. 8 depicts a schematic of an exemplary system for reducing power in an SRAM. During normal operation node 810 is driven to a low logical value and node 811 is driven to a high logical value. Because node 810 is driven to a low logical value and node 811 is driven to a high logical value, PFETs, PFET1A-PFET255A drive node 809 to a voltage near VDD1. During standby operation node 810 is driven to a high logical value and node 811 is driven to a low logical value. Because node 810 is driven to a high logical value and node 811 is driven to a low logical value, PFET1C drives node 809 to a voltage lower than VDD1. In this example, PFET, PFET1C, is designed to drop the voltage on node 809 to a voltage lower than VDD1. PFET1C may be changed, for example, by changing the width or the length of the PFET. Other methods of changing PFET1C may be used. Because PFET1C drops the voltage on node 809 to a lower voltage than VDD1, the power used due to leakage is reduced.

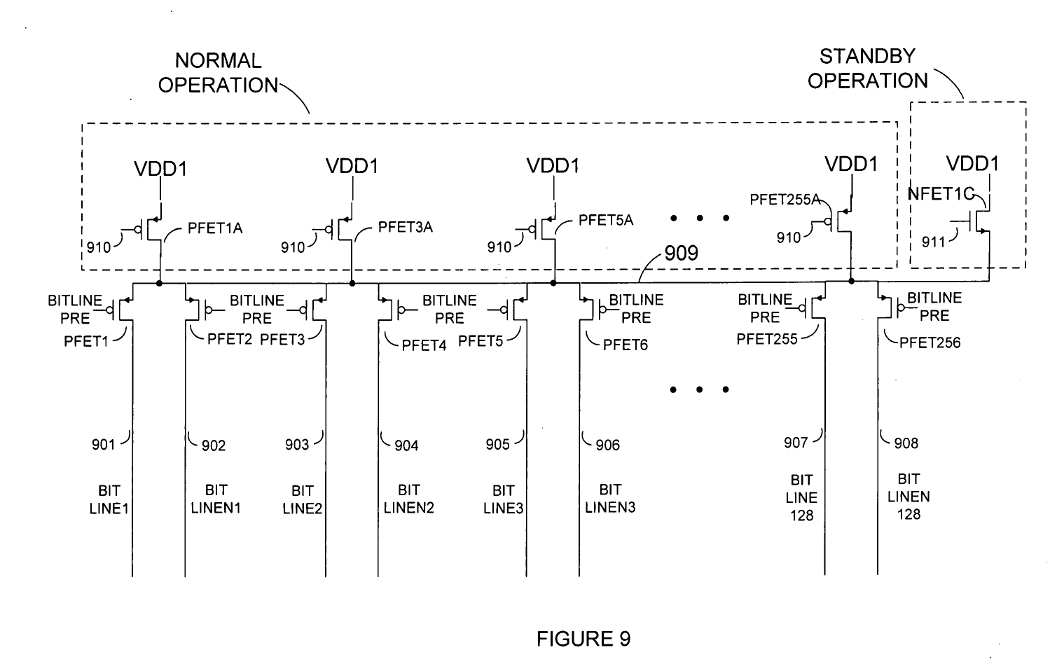

FIG. 9 depicts a schematic of an exemplary system for reducing power in an SRAM. During normal operation node 910 is driven to a low logical value and node 911 is driven to a low logical value. Because node 910 is driven to a low logical value and node 911 is driven to a low logical value, PFETs, PFET1A-PFET255A drive node 909 to a voltage near VDD1. During standby operation node 910 is driven to a high logical value and node 911 is driven to a high logical value. Because node 910 is driven to a high logical value and node 911 is driven to a high logical value, NFET1C drives node 909 to a voltage of approximately VDD1-Vₜ (threshold voltage). In this example, NFET, NFET1C, drops the voltage on node 909 to a voltage one Vₜ lower than VDD1. Because NFET1C drops the voltage on node 909 to a voltage one Vₜ lower than VDD1, the power used due to leakage is reduced.

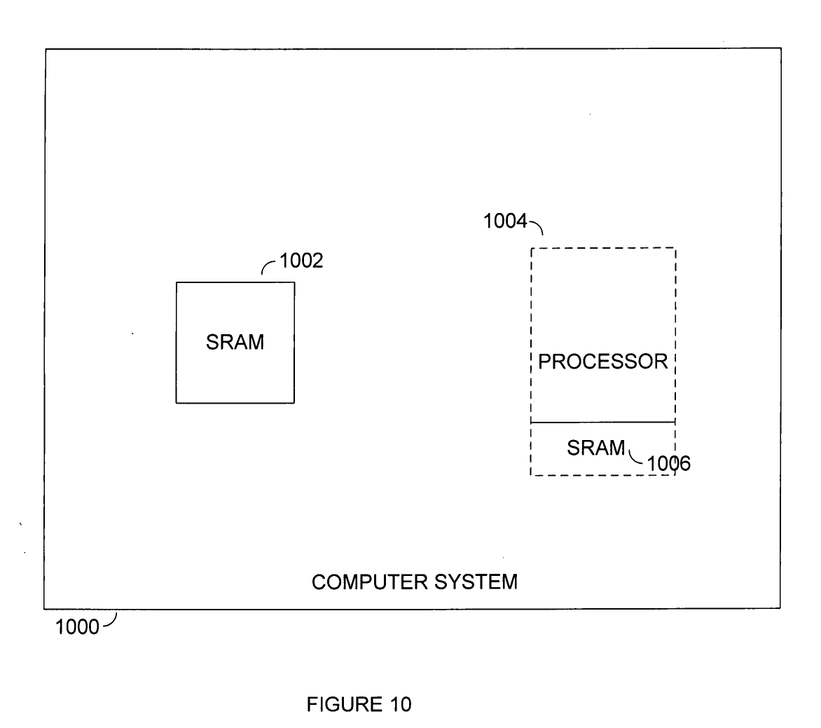

FIG. 10 depicts a block diagram of an exemplary computer system for reducing power on an SRAM. Block 1000 represents a computer system that includes at least one processor, 1004, the processor 1004 containing some on-chip SRAM, 1006, and at least one stand-alone SRAM memory, 1002. In this computer system, 1000, at least one stand-alone memory, 1002, contains a system for reducing power on an SRAM. In this computer system, 1000, at least one processor, 1004, containing on-chip SRAM, 1006, contains a system for reducing power on an SRAM.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A method for reducing power in an SRAM comprising:
a) applying a first voltage to all bitlines of a section of the SRAM in standby operation;
b) applying a second voltage to all the bitlines of a section of the SRAM in normal operation;
c) wherein the first voltage is not greater than the second voltage.

2) The method for reducing power in an SRAM as recited in claim 1, wherein the first voltage is applied by switching to a first voltage reference.

3) The method for reducing power in an SRAM as recited in claim 1, wherein the second voltage is applied by switching to a second voltage reference.

4) The method for reducing power in an SRAM as recited in claim 2, wherein switching is performed by one or more transistors.

5) The method for reducing power in an SRAM as recited in claim 3, wherein switching is performed by one or more transistors.

6) The method for reducing power in an SRAM as recited in claim 2, wherein switching is performed by one or more PFETs.

7) The method for reducing power in an SRAM as recited in claim 3, wherein switching is performed by one or more PFETs.

8) The method for reducing power in an SRAM as recited in claim 2, wherein switching is performed by one or more NFETs.

9) A power reducing system for an SRAM comprising:
a) a first switch;
b) a second switch;
c) such that when the first switch is closed a first voltage reference is applied to all bitlines of a section of the SRAM in standby operation;
d) such that when the second switch is closed a second voltage reference is applied to all bitlines of a section of the SRAM in normal operation;
e) wherein the first voltage is not greater than the second voltage.

10) The power reducing system for an SRAM as recited in claim 9, wherein the first switch comprises one or more transistors.

11) The power reducing system for an SRAM as recited in claim 9, wherein the second switch comprises one or more transistors.

12) The power reducing system for an SRAM as recited in claim 9, wherein the first switch comprises one or more PFETs.

13) The power reducing system for an SRAM as recited in claim 9, wherein the second switch comprises one or more PFETs.

14) The power reducing system for an SRAM as recited in claim 9, wherein the first switch comprises one or more NFETs.

15) A computer system comprising:
a) at least one processor;
b) at least one SRAM;
c) wherein at least one SRAM contains a power reducing system for an SRAM;
d) wherein the power reducing system for an SRAM applies a first voltage to all bitlines of a section of the SRAM in standby operation;
e) wherein the power reducing system for an SRAM applies a second voltage to all bitlines of a section of the SRAM in normal operation;
f) wherein the first voltage is not greater than the second voltage.

16) The computer system as recited in claim 15, wherein the first voltage is applied by switching to a first voltage reference.

17) The computer system as recited in claim 15, wherein the second voltage is applied by switching to a second voltage reference.

18) The computer system as recited in claim 16, wherein switching is performed by one or more transistors.

19) The computer system as recited in claim 17, wherein switching is performed by one or more transistors.

20) The computer system as recited in claim 16, wherein switching is performed by one or more PFETs.

21) The computer system as recited in claim 17, wherein switching is performed by one or more PFETs.

22) The computer system as recited in claim 16, wherein switching is performed by one or more NFETs.
